(19) United States
(12) Patent Application Publication
(10) Pub. No.: US 2025/0164709 A1
(43) Pub. Date: May 22, 2025

(54) OPTICAL PACKAGE STRUCTURE, PACKAGE STRUCTURE, AND METHOD FOR FORMING OPTICAL PACKAGE STRUCTURE

(71) Applicant: Taiwan Semiconductor Manufacturing Company, Ltd., Hsinchu (TW)

(72) Inventors: Ming-Fa CHEN, Taichung City (TW); Chih-Tsung TSAI, Tainan City (TW)

(73) Assignee: Taiwan Semiconductor Manufacturing Company, Ltd., Hsinchu (TW)

(21) Appl. No.: 18/513,110

(22) Filed: Nov. 17, 2023

(51) Int. Cl. G02B 6/42; H01L 23/00; H01L 23/13; H01L 23/14; H01L 25/18

(52) U.S. Cl. CPC G02B 6/4214; H01L 23/13; H01L 24/13; H01L 24/14; H01L 25/18; H01L 23/147; H01L 24/04; H01L 24/05; H01L 24/08; H01L 24/16; H01L 24/32; H01L 24/73; H01L 24/80; H01L 2224/0401; H01L 2224/05666; H01L 2224/05681; H01L 2224/05686; H01L 2224/08145; H01L 2224/13109; H01L 2224/13111; H01L 2224/13113; H01L 2224/13116; H01L 2224/13118; H01L 2224/1312; H01L 2224/13139; H01L 2224/13144; H01L 2224/13147; H01L 2224/14517; H01L 2224/16227; H01L 2224/32225; H01L 2224/73204; H01L 2224/8001; H01L 2224/80201; H01L 2224/80357; H01L 2224/80895; H01L 2224/80896; H01L 2924/014; H01L 2924/04941; H01L 2924/04953

(57) ABSTRACT

An optical package structure is provided. The optical package structure includes a photonic integrated circuit die, an electronic integrated circuit die, an oxide layer, and a silicon carrier. The photonic integrated circuit die includes a coupler. The electronic integrated circuit die is bonded to the photonic integrated circuit die. The oxide layer is adjacent to the electronic integrated circuit die. The silicon carrier includes a first part over the electronic integrated circuit die and a second part over the oxide layer. A trench is formed in the second part of the silicon carrier.

### BACKGROUND

The semiconductor industry continues to improve the integration density of various electronic components (e.g., transistors, diodes, resistors, capacitors, etc.) by continual reductions in minimum feature size, which allow more components to be integrated into a given area. The individual dies are typically packaged separately. A package not only provides protection for semiconductor devices from environmental contaminants, but also provides a connection interface for the semiconductor devices packaged therein.

Three dimensional integrated circuits (3DICs) are a recent development in semiconductor packaging in which multiple semiconductor dies are stacked upon one another, such as package-on-package (PoP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, as examples. However, there are many challenges related to 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1K illustrate cross-sectional views of various stages of manufacturing an optical package structure, in accordance with some embodiments.

FIG. 1K′ illustrates a cross-sectional view of an optical package structure, in accordance with some embodiments.

FIG. 2 illustrates a cross-sectional view of a package structure, in accordance with some embodiments.

FIG. 3A, FIG. 3B, and FIG. 3C illustrate cross-sectional views of various stages of manufacturing an interposer, in accordance with some embodiments.

FIG. 4 illustrates a cross-sectional view of a package structure including the interposer illustrated in FIG. 3C, in accordance with some embodiments.

FIG. 5 illustrates a cross-sectional view of a package structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first feature and the second feature are formed in direct contact, and may also include embodiments in which additional features may be formed between the first feature and the second feature, such that the first feature and the second feature may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “under,” “above,” “upper,” “over,” and the like, may be used herein for ease of description to describe one element or feature's relationship to another element or feature as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be understood that additional operations can be provided before, during, and after the method, and some of the operations described can be replaced or eliminated for other embodiments of the method.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed over intermediate structures as well as the final structure. Additionally, the structures and methods disclosed herein may be used in conjunction with testing methodologies that incorporate intermediate verification of known good dies to increase the yield and decrease costs.

As the integration density of various electronic components is improved, optical properties of the formed semiconductor devices have garnered attention. Transmission of optical signals may be affected by different reasons, including the optical path that optical signals have to travel. Some embodiments of the present disclosure provide an optical package structure that effectively shortens the optical path. In addition, some embodiments of the present disclosure may be applied to, but are not limited to chip-on-wafer-on-substrate (CoWoS) package structure.

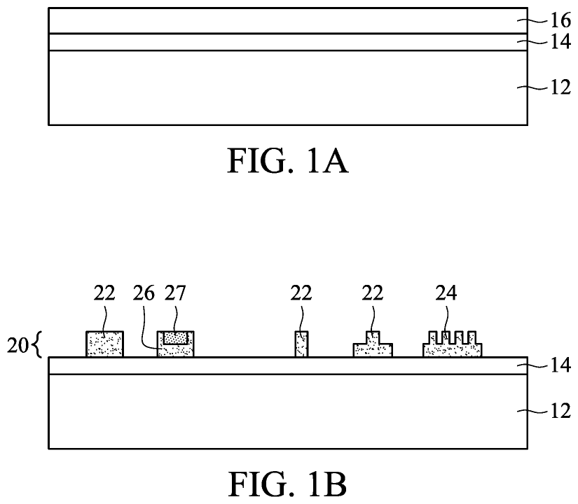

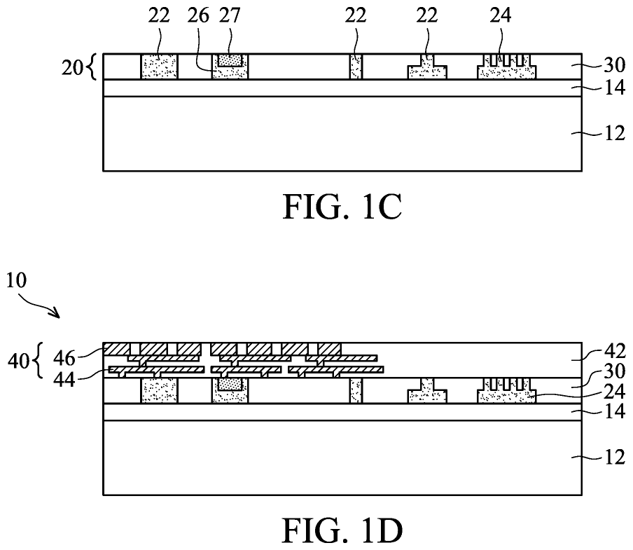

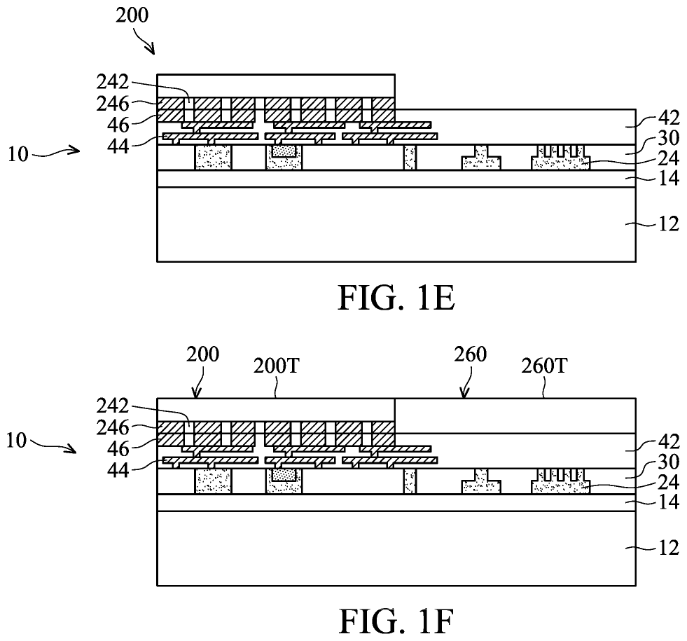

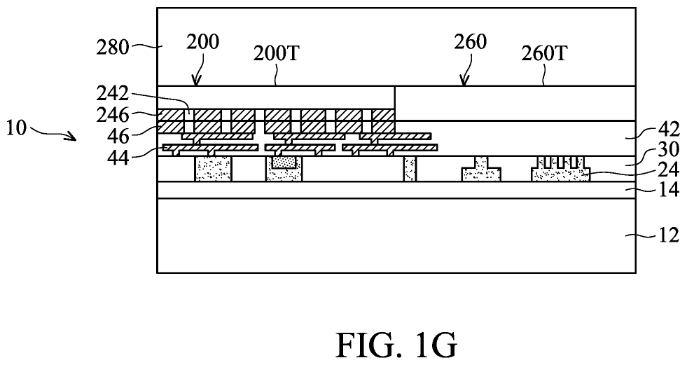

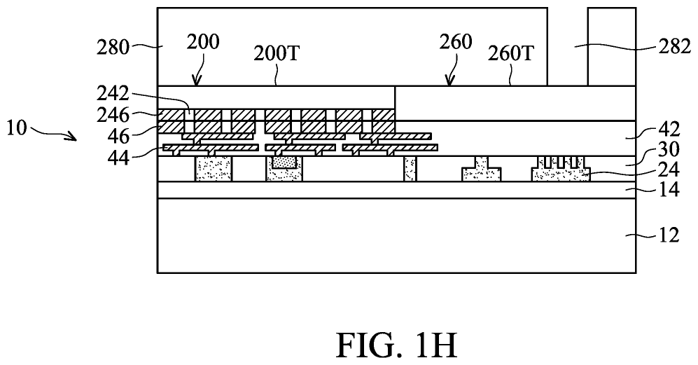

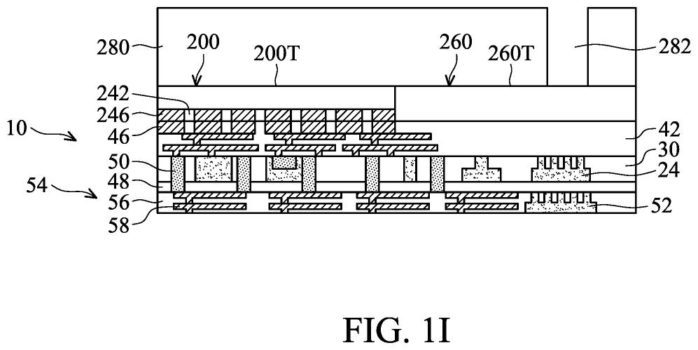

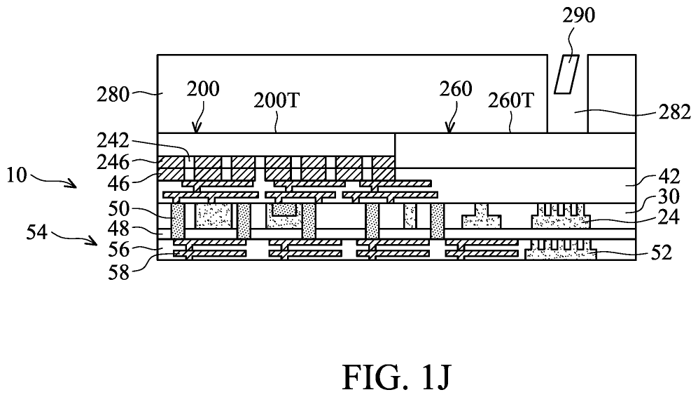

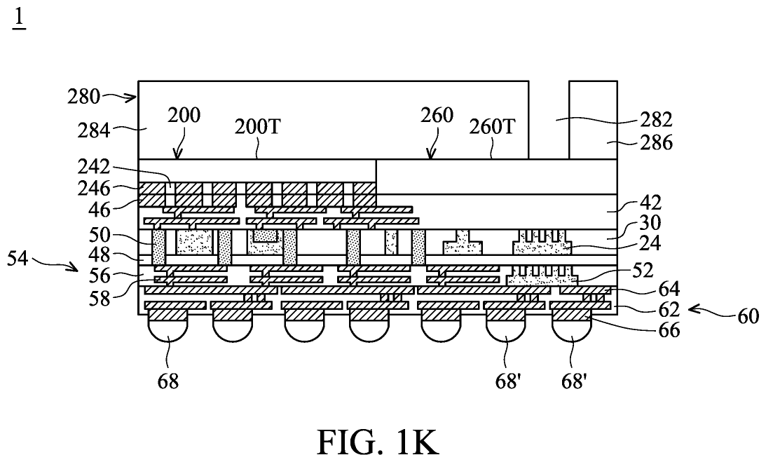

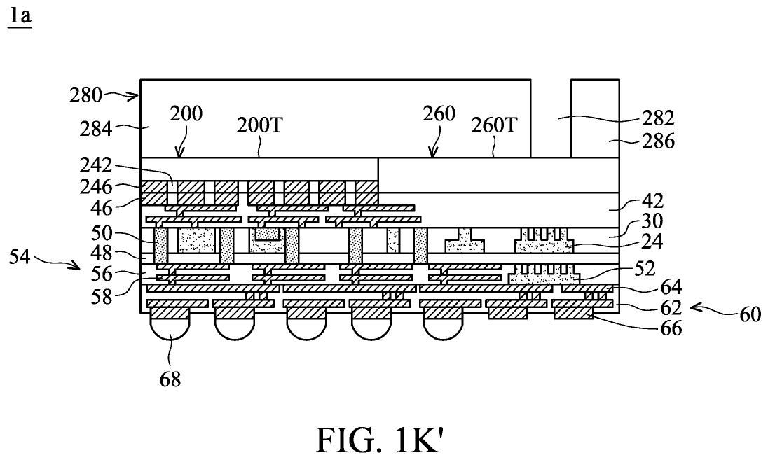

FIG. 1A to FIG. 1K illustrate cross-sectional views of various stages of manufacturing an optical package structure 1 (denoted in FIG. 1K), in accordance with some embodiments.

As shown in FIG. 1A, an photonic integrated circuit (PIC) die 10 (denoted in FIG. 1D) is formed by step FIG. 1A to FIG. 1C, in accordance with some embodiments. The photonic integrated circuit die 10 includes a substrate 12, an insulator layer 14 formed over the substrate 12, and a silicon layer 16 formed over the insulator layer 14. In some embodiments, the substrate 12, the insulator layer 14, and the silicon layer 16 are collectively be part of a silicon-on-insulator (SOI) substrate.

The substrate 12 may be a semiconductor wafer, such as a silicon wafer. Alternatively or additionally, the substrate 12 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, and/or indium arsenide. Alloy semiconductor materials may include, but are not limited to, SiGe, GaAsP, AlInAs, AlGaAs, GaInAs, GaInP, and/or GaInAsP.

The insulator layer 14 may be silicon oxide, silicon nitride, germanium oxide, germanium nitride, combinations of these, or another applicable material. In some embodiments, the insulator layer 14 may be formed over the substrate 12 by chemical vapor deposition (CVD), physical vapor deposition (PVD), plasma enhanced chemical vapor deposition (PECVD), spin coating, lamination or another suitable deposition technique.

Next, as shown in FIG. 1B, the silicon layer 16 is patterned to form the optical components 20, in accordance with some embodiments. The optical components 20 include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. The optical components 20 are formed by a patterning process. The patterning process includes a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process may include a dry etching process or a wet etching process.

In some embodiments, the optical components 20 include a plurality of waveguides 22, a coupler 24, a modulator 26 and a germanium modulator 27. The waveguides 22 may be used to guide electromagnetic waves with minimal loss of energy by restricting the transmission of energy to two dimensions. In some embodiments, multiple waveguides may be formed as a single continuous structure. The coupler 24 may be integrated with the waveguides 22, and may be formed with the waveguides 22. The coupler 24 may be a photonic structure that allows optical signals and/or optical power to be transferred between the waveguides 22. In some embodiments, the coupler 24 includes a grating coupler (GC).

The modulator 26 is optically coupled to the waveguides 22 to receive electrical signals and generate corresponding optical signals within the waveguides 22 by modulating optical power within the waveguides 22. The germanium modulator 27 may be formed over the modulator 26. In some embodiments, the germanium modulator 27 is formed by partially etching a portion of the silicon layer 16 to form a recess and growing an epitaxial material in the recess on the remaining silicon layer 16. The silicon layer 16 may be etched using photolithography and etching techniques. The epitaxial material may include a semiconductor material, such as doped or undoped germanium.

Although the configurations or arrangements of the optical component 20 including the waveguides 22, the coupler 24, the modulator 26, and the germanium modulator 27 are shown in FIG. 1B, the configurations or arrangements of optical component 20 may be adjusted according to actual application.

Afterwards, as shown in FIG. 1C, a dielectric layer 30 is formed over the optical component 20, in accordance with some embodiments. More specifically, the dielectric layer 30 is formed over the waveguides 22, the coupler 24, the modulator 26, and the germanium modulator 27. The dielectric layer 30 is used to separate the individual optical components 20. In some embodiments, the dielectric layer 30 includes silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the dielectric layer 42 may be formed over the dielectric layer 30 by chemical vapor deposition (CVD), physical vapor deposition (PVD), plasma enhanced chemical vapor deposition (PECVD), spin coating, lamination or another suitable deposition technique.

Next, as shown in FIG. 1D, an interconnect structure 40 is formed over the dielectric layer 30, in accordance with some embodiments. The interconnect structure 40 includes a plurality of conductive layers 44 and a plurality of conductive pads 46 both embedded in a dielectric layer 42. The interconnect structure 40 may be used as a redistribution (RDL) structure for routing. The photonic integrated circuit die 10 is formed, having optical components 20 and interconnect structure 40 for connecting to other dies or chips.

It should be noted that one or more optical components may be formed in the dielectric layer 42. The optical components may include optical waveguides (e.g., ridge waveguides, rib waveguides, buried channel waveguides, diffused waveguides, slab waveguides etc.), couplers (e.g., grating couplers, edge couplers, etc.), optical switches (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like.

In some embodiments, the dielectric layer 42 include silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. In some embodiments, the dielectric layer 42 may be formed over the dielectric layer 30 by chemical vapor deposition (CVD), physical vapor deposition (PVD), plasma enhanced chemical vapor deposition (PECVD), spin coating, lamination or another suitable deposition technique. In some embodiments, the conductive layers 44 and the conductive pads 46 are made of conductive materials, such as copper (Cu), copper alloy, aluminum (Al), aluminum alloys, combinations thereof or another applicable material.

Afterwards, as shown in FIG. 1E, an electronic integrated circuit (EIC) die 200 is bonded to a first region of the photonic integrated circuit die 10, in accordance with some embodiments. The electronic integrated circuit die 200 includes a plurality of conductive pads 246 embedded in a dielectric layer 242, and the conductive pads 246 are bonded to the conductive pads 46.

The electronic integrated circuit die 200 may include integrated circuits for interfacing with the various photonic components formed in the dielectric layer 42 of the interconnect structure 40 or in the dielectric layer 30 of the photonic integrated circuit die 10. The electronic integrated circuit die 200 is used to communicate with one or more of the optical components 20 in the photonic integrated circuit die 10 using electrical signals.

In some embodiments, the electronic integrated circuit die 200 includes suitable device, such as a logic die, a 3DIC die, a CPU, a GPU, a SoC die, a MEMS die, or a combination thereof. Although one electronic integrated circuit die 200 is formed in FIG. 1E, two or more electronic integrated circuit dies 200 may be bonded to the interconnect structure 40.

Before the electronic integrated circuit die 200 and the photonic integrated circuit die 10 are bonded together, a surface treatment is performed to active the surfaces of the conductive pads 246 and the conductive pads 46. In some embodiments, the surface treatment includes a dry treatment, a wet treatment, a plasma treatment, exposure to an inert gas, exposure to H₂, exposure to N₂, exposure to O₂, the like, or combinations thereof. After the surface treatment, a cleaning process is performed over the electronic integrated circuit die 200 and the photonic integrated circuit die 10. Afterwards, the electronic integrated circuit die 200 and the photonic integrated circuit die 10 are aligned, such that the conductive pads 246 of electronic integrated circuit die 200 can be bonded to the conductive pads 46 of the interconnect structure 40, and the dielectric layer 242 can be bonded to the dielectric layer 42 of the interconnect structure 40 of the photonic integrated circuit die 10. In some embodiments, the alignment of the electronic integrated circuit die 200 and the photonic integrated circuit die 10 may be achieved by using an optical sensing method.

After the alignment is performed, the electronic integrated circuit die 200 and the photonic integrated circuit die 10 may be bonded together by a hybrid bonding process. The hybrid bonding involves at least two types of bonding, including metal-to-metal bonding and dielectric-to-dielectric bonding. The electronic integrated circuit die 200 and the photonic integrated circuit die 10 are hybrid bonded together by the application of pressure and heat.

Next, as shown in FIG. 1F, an oxide layer 260 is formed over a second region of the photonic integrated circuit die 10, in accordance with some embodiments. The second region is different from the first region. In some embodiments, the second region is adjacent to the first region. In some embodiments, the oxide layer 260 is formed over the second region of the photonic integrated circuit die 10 by chemical vapor deposition (CVD), physical vapor deposition (PVD), plasma enhanced chemical vapor deposition (PECVD), spin coating, lamination or another suitable deposition technique. In some embodiments, the oxide layer 260 is formed adjacent to the electronic integrated circuit die 200. In some embodiments, the top surface 260T of the oxide layer 260 is substantially level with the top surface 200T of the electronic integrated circuit die 200.

In some embodiments, the oxide layer 260 may include materials such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr)TiO₃ (BST), silicon nitride (SiN), silicon oxynitride (SiON), combinations thereof, and the like. In some embodiments, the oxide layer 260 may include materials such as TEOS oxide, undoped silica glass (USG), doped silicon oxide, such as BPSG, FSG, PSG, BSG.

Next, as shown in FIG. 1G, a silicon carrier 280 is attached to the electronic integrated circuit die 200 and the oxide layer 260, in accordance with some embodiments. In some embodiments, the silicon carrier 280 is attached to the electronic integrated circuit die 200 and the oxide layer 260 via bonding structures formed in the silicon carrier 280, the electronic integrated circuit die 200, and the oxide layer 260.

Then, as shown in FIG. 1H, a trench 282 is formed in the silicon carrier 280, in accordance with some embodiments. The trench 282 may be formed using a suitable combination of photolithography processes and etching processes. The photolithography processes may include photoresist deposition, photoresist coating (e.g., spin-on coating), soft baking, mask aligning, exposure, post-exposure baking, development, rinsing and drying (e.g., hard baking). The etching processes may include a dry etching process, a wet etching process, or a combination thereof.

Then, as shown in FIG. 1I, the substrate 12 and the insulator layer 14 are removed to expose the optical components 20, a dielectric layer 48 is formed below the dielectric layer 30, and a metal reflector 52 and an interconnect structure 54 are formed below the dielectric layer 48, in accordance with some embodiments. A plurality of through dielectric vias (TDVs) 50 may be formed through the dielectric layer 30 and the dielectric layer 48. The through dielectric vias 50 may be in direct contact with the conductive layers 44.

The metal reflector 52 may be formed in the interconnect structure 54. In some embodiments, the metal reflector 52 at least partially overlaps the coupler 24 and the trench 282 vertically. The metal reflector 52 may be used to reflect optical signals, and thus the optical coupling on the coupler 24 is optimized.

The interconnect structure 54 includes a plurality of conductive layers 58 embedded in a dielectric layer 56. The interconnect structure 54 may be used as a redistribution (RDL) structure for routing. In some embodiments, the dielectric layer 56 include silicon oxide (SiO₂), silicon nitride (SiN), silicon carbide (SiC), silicon oxynitride (SiON), silicon carbon nitride (SiCN), silicon oxide carbonitride (SiOCN), and a combination thereof. In some embodiments, the dielectric layer 56 may be formed by chemical vapor deposition (CVD), physical vapor deposition (PVD), plasma enhanced chemical vapor deposition (PECVD), spin coating, lamination or another suitable deposition technique.

In some embodiments, the conductive layers 58 are made of conductive materials, such as copper (Cu), copper alloy, aluminum (Al), aluminum alloys, combinations thereof or another applicable material. In some embodiments, the conductive layers 58 may be formed by chemical vapor deposition (CVD), physical vapor deposition (PVD), plasma enhanced chemical vapor deposition (PECVD), spin coating, lamination or another suitable deposition technique.

Next, as shown in FIG. 1J, a fiber array unit (FAU) 290 may be placed in the trench 282, in accordance with some embodiments. The fiber array unit 290 may be used as an optical input/output port to the photonic integrated circuit die 10. Optical signals leaving the fiber array unit 290 may enter the coupler 24 without passing through the silicon carrier 280. Therefore, optical path is shortened, and the optical coupling on the coupler 24 is further improved. In addition, since the trench 282 is formed directly over the coupler 24, the alignment accuracy between the fiber array unit 290 and the coupler 24 is improved. Furthermore, transmission speed of optical signals may become faster, and power consumption can be reduced.

Next, as shown in FIG. 1K, a bonding layer 60 is formed below the interconnect structure 54, in accordance with some embodiments. The bonding layer 60 includes a plurality of conductive layers 64 formed in a dielectric layer 62, a plurality of under bump metallization (UBM) layers 66 below the conductive layers 64, a plurality of conductive connectors 68 formed below the under bump metallization layers 66 and the dielectric layer 62, and a plurality of dummy conductive connectors 68′ formed below the under bump metallization layers 66 and the dielectric layer 62.

In some embodiments, the dielectric layer 62 include silicon oxide (SiO₂), silicon nitride (SiN), silicon carbide (SiC), silicon oxynitride (SiON), silicon carbon nitride (SiCN), silicon oxide carbonitride (SiOCN), and a combination thereof. In some embodiments, the dielectric layer 62 may be formed by chemical vapor deposition (CVD), physical vapor deposition (PVD), plasma enhanced chemical vapor deposition (PECVD), spin coating, lamination or another suitable deposition technique.

In some embodiments, the conductive layers 64 are made of conductive materials, such as copper (Cu), copper alloy, aluminum (Al), aluminum alloys, combinations thereof or another applicable material. In some embodiments, the conductive layers 64 may be formed by chemical vapor deposition (CVD), physical vapor deposition (PVD), plasma enhanced chemical vapor deposition (PECVD), spin coating, lamination or another suitable deposition technique.

The under bump metallization layers 66 may contain an adhesion layer and/or a wetting layer. In some embodiments, the under bump metallization layers 66 are made of titanium (Ti), titanium nitride (TiN), tantalum nitride (TaN), tantalum (Ta), or the like. In some embodiments, the under bump metallization layers 66 further includes a copper seed layer. In some embodiments, the under bump metallization layers 66 are formed by electroplating, electroless plating, printing, a chemical vapor deposition (CVD) process, a physical vapor process, or another applicable process.

The conductive connectors 68 and the dummy conductive connectors 68′ are made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 68 and the dummy conductive connectors 68′ are formed by electroplating, electroless plating, printing, a chemical vapor deposition (CVD) process, a physical vapor process, or another applicable process. Each dummy conductive connector 68′ at least partially overlaps the metal reflector 52 vertically. The conductive connectors 68 are electrically connected to the electronic integrated circuit die 200, and the dummy conductive connectors 68′ are not electrically connected to the electronic integrated circuit die 200. In some embodiments, the dummy conductive connectors 68′ may be directly under the coupler 24 and the metal reflector 52.

In short, a method for forming the optical package structure 1 is provided. The method includes forming the photonic integrated circuit die 10 and forming the electronic integrated circuit die 200 over the photonic integrated circuit die 10. The method also includes forming the oxide layer 260 adjacent to the electronic integrated circuit die 200. The method further includes attaching the silicon carrier 280 to the electronic integrated circuit die 200 and the oxide layer 260 and forming the trench 282 in the silicon carrier 280, so that part of the top surface 260T of the oxide layer 260 is exposed.

In some embodiments, the top surface 260T of the oxide layer 260 is substantially level with the top surface 200T of the electronic integrated circuit die 200. In some embodiments, the photonic integrated circuit die 10 includes the substrate 12 and the coupler 24 over the substrate 12. In some embodiments, the trench 282 is formed directly over the coupler 24. In some embodiments, the method further includes removing the substrate 12 of the photonic integrated circuit die 10 after the trench 282 is formed. In some embodiments, the method further includes placing the fiber array unit 290 in the trench 282.

The optical package structure 1 includes the photonic integrated circuit die 10, the electronic integrated circuit die 200, the oxide layer 260, and the silicon carrier 280. The photonic integrated circuit die 10 includes the coupler 24. The electronic integrated circuit die 200 is bonded to the photonic integrated circuit die 10. The oxide layer 260 is adjacent to the electronic integrated circuit die 200. The silicon carrier 280 includes a first part 284 over the electronic integrated circuit die 200 and a second part 286 over the oxide layer 260. The trench 282 is formed in the second part 286 of the silicon carrier 280.

In some embodiments, the trench 282 at least partially overlaps the coupler 24 vertically. In some embodiments, the width of the first part 284 is greater than the width of the electronic integrated circuit die 200, so the electronic integrated circuit die 200 is not exposed and is protected. In some embodiments, the width of the first part 284 of the silicon carrier 280 is greater than the width of the second part 286 of the silicon carrier 280. In some embodiments, the thickness of the first part 284 of the silicon carrier 280 is greater than the thickness of the oxide layer 260.

In some embodiments, the optical package structure 1 further includes the dielectric layer 56 and the metal reflector 52 formed in the dielectric layer 56, and the metal reflector 52 is formed under the oxide layer 260. In some embodiments, the metal reflector 52 at least partially overlaps the coupler 24 and the trench 282 vertically. In some embodiments, the width of the metal reflector 52 is greater than the width of the coupler 24.

In some embodiments, the optical package structure 1 further includes the conductive connectors 68 and the dummy conductive connectors 68′ formed under the dielectric layer 56. In some embodiments, the conductive connectors 68 are electrically connected to the electronic integrated circuit die 200, and the dummy conductive connectors 68′ are not electrically connected to the electronic integrated circuit die 200. In some embodiments, each dummy conductive connector 68′ at least partially overlaps the metal reflector 52 vertically. In some embodiments, the photonic integrated circuit die 10 further includes the waveguide 22 adjacent to the coupler 24.

Due to the trench 282 formed in the silicon carrier 280, the fiber array unit 290 may be placed in the trench 282. Optical signals leaving the fiber array unit 290 may enter the coupler 24 without passing through the silicon carrier 280. Therefore, optical path is shortened, and the optical coupling on the coupler 24 is further improved. In addition, the alignment accuracy between the fiber array unit 290 and the coupler 24 is improved. Furthermore, transmission speed of optical signals may become faster, and power consumption can be reduced.

FIG. 1K′ illustrates a cross-sectional view of an optical package structure 1a, in accordance with some embodiments. The optical package structure 1a is an alternate embodiment which may be similar to the optical package structure 1 of FIG. 1K. Processes and materials used to form the optical package structure 1a may be similar to, or the same as, those used to form the optical package structure 1 and are not repeated herein. One of the main differences between the optical package structure 1a and the optical package structure 1 is that no dummy conductive connectors 68′ are formed. That is, no conductive connectors are formed under the coupler 24 and the metal reflector 52.

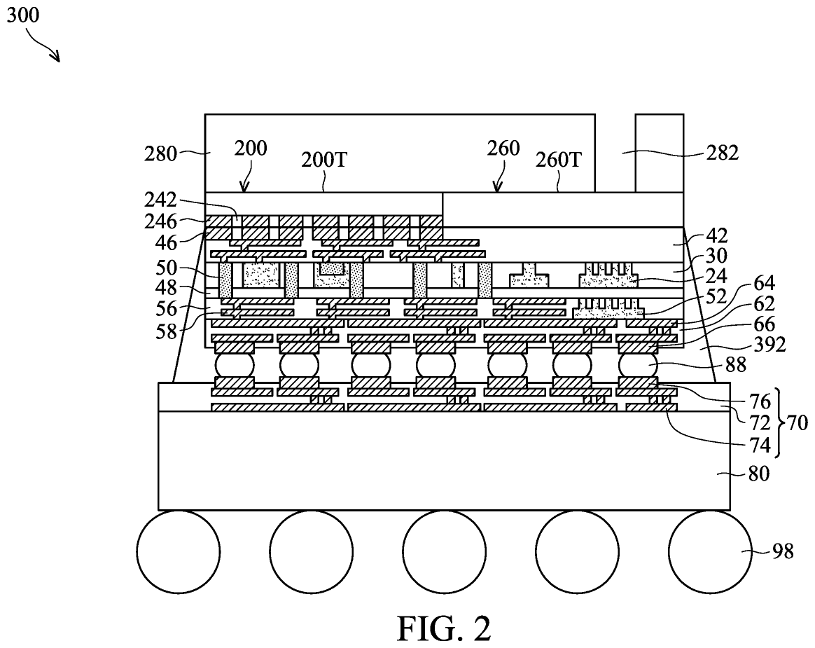

FIG. 2 illustrates a cross-sectional view of a package structure 300, in accordance with some embodiments. The optical package structure 1 may be bonded to an interconnect structure 70 formed over a package substrate 80 to form the package structure 300. The interconnect structure 70 includes a plurality of conductive layers 74 embedded in a dielectric layer 72, a plurality of under bump metallization layers 76 formed over the conductive layers 74, and a plurality of conductive connectors (not denoted because they are bonded to the conductive connectors 68 to form a plurality of joint conductive connectors 88) formed over the under bump metallization layers 76.

In some embodiments, the dielectric layer 72 include silicon oxide (SiO₂), silicon nitride (SiN), silicon carbide (SiC), silicon oxynitride (SiON), silicon carbon nitride (SiCN), silicon oxide carbonitride (SiOCN), and a combination thereof. In some embodiments, the dielectric layer 72 may be formed by chemical vapor deposition (CVD), physical vapor deposition (PVD), plasma enhanced chemical vapor deposition (PECVD), spin coating, lamination or another suitable deposition technique.

In some embodiments, the conductive layers 74 are made of conductive materials, such as copper (Cu), copper alloy, aluminum (Al), aluminum alloys, combinations thereof or another applicable material. In some embodiments, the conductive layers 74 may be formed by chemical vapor deposition (CVD), physical vapor deposition (PVD), plasma enhanced chemical vapor deposition (PECVD), spin coating, lamination or another suitable deposition technique.

The under bump metallization layers 76 may contain an adhesion layer and/or a wetting layer. In some embodiments, the under bump metallization layers 76 are made of titanium (Ti), titanium nitride (TiN), tantalum nitride (TaN), tantalum (Ta), or the like. In some embodiments, the under bump metallization layers 76 further includes a copper seed layer. In some embodiments, the under bump metallization layers 76 are formed by electroplating, electroless plating, printing, a chemical vapor deposition (CVD) process, a physical vapor process, or another applicable process. The conductive connectors 78 are made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors formed over the under bump metallization layers 76 are formed by electroplating, electroless plating, printing, a chemical vapor deposition (CVD) process, a physical vapor process, or another applicable process.

The optical package structure 1 may be in direct contact with the interconnect structure 70 and the package substrate 80 using, e.g. a pick-and-place process. A reflow process is performed to bond the conductive connectors 68 and the respective conductive connectors formed over the under bump metallization layers 76 to form the joint conductive connectors 88. A plurality of conductive connectors 98 may be formed under the package substrate 80.

In some embodiments, an underfill layer 392 is dispensed into the gap between the optical package structure 1 and the package substrate 80. The underfill layer 392 is also formed in the gap between the joint conductive connectors 88. In some embodiments, the underfill layer 392 includes a polymer, epoxy, molding underfill, or the like. In some embodiments, the underfill layer 392 is formed by a capillary flow process.

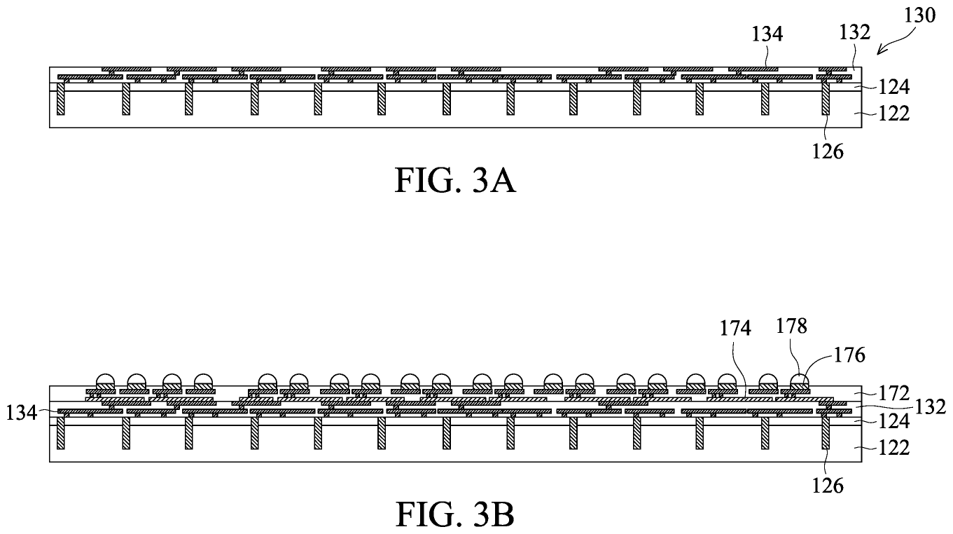

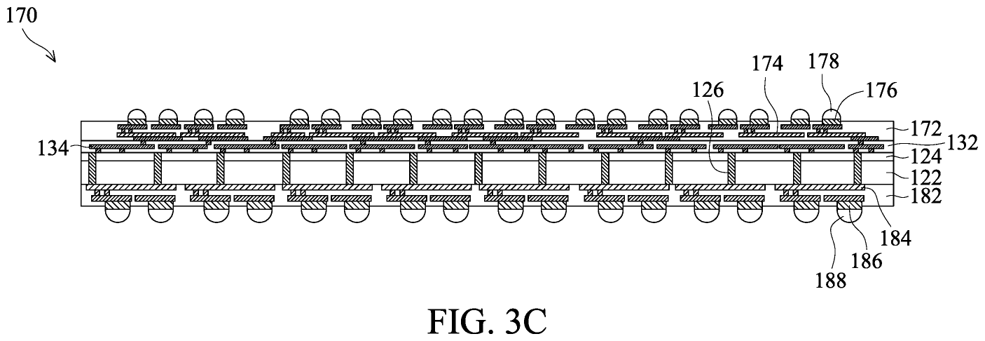

FIG. 3A, FIG. 3B, and FIG. 3C illustrate cross-sectional views of various stages of manufacturing an interposer 170, in accordance with some embodiments.

As shown in FIG. 3A, a dielectric layer 124 is formed on a substrate 122, and through vias (TVs) 126 are formed through the dielectric layer 124 and the substrate 122, in accordance with some embodiments. The substrate 122 may be a semiconductor wafer such as a silicon wafer. Alternatively or additionally, the substrate 122 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, and/or indium arsenide. Alloy semiconductor materials may include, but are not limited to, SiGe, GaAsP, AlInAs, AlGaAs, GaInAs, GaInP, and/or GaInAsP.

The dielectric layer 124 include silicon oxide (SiO₂), silicon nitride (SiN), silicon carbide (SiC), silicon oxynitride (SiON), silicon carbon nitride (SiCN), silicon oxide carbonitride (SiOCN), and a combination thereof. In some embodiments, the dielectric layer 124 may be formed by chemical vapor deposition (CVD), physical vapor deposition (PVD), plasma enhanced chemical vapor deposition (PECVD), spin coating, lamination or another suitable deposition technique.

The through vias 126 are formed by forming trenches through the dielectric layer 124 and the top portion of the substrate 122, and then a barrier layer (not shown) is formed in each of the trench and a conductive material is formed on the barrier layer. Once the trenches have been filled, the excess barrier layer and the conductive materials are removed by a planarization process, such as chemical polishing mechanical polishing (CMP) process. In some embodiments, the barrier layer includes tantalum nitride, although other materials, such as tantalum, titanium, titanium nitride, or the like, may also be used. In some embodiments, the through vias 126 are made of conductive materials, such as copper (Cu), copper alloy, aluminum (Al), aluminum alloys, combinations thereof or another applicable material. In some embodiments, the through vias 126 may be formed by chemical vapor deposition (CVD), physical vapor deposition (PVD), plasma enhanced chemical vapor deposition (PECVD), spin coating, lamination or another suitable deposition technique.

Afterwards, an interconnect structure 130 is formed over the dielectric layer 124. The interconnect structure 130 includes a plurality of conductive layers 134 embedded in a dielectric layer 132. The interconnect structure 130 may be used as a redistribution (RDL) structure for routing.

The dielectric layer 132 include silicon oxide (SiO₂), silicon nitride (SiN), silicon carbide (SiC), silicon oxynitride (SiON), silicon carbon nitride (SiCN), silicon oxide carbonitride (SiOCN), and a combination thereof. In some embodiments, the dielectric layer 132 may be formed by chemical vapor deposition (CVD), physical vapor deposition (PVD), plasma enhanced chemical vapor deposition (PECVD), spin coating, lamination or another suitable deposition technique.

In some embodiments, the conductive layers 134 are made of conductive materials, such as copper (Cu), copper alloy, aluminum (Al), aluminum alloys, combinations thereof or another applicable material. In some embodiments, the conductive layers 134 may be formed by chemical vapor deposition (CVD), physical vapor deposition (PVD), plasma enhanced chemical vapor deposition (PECVD), spin coating, lamination or another suitable deposition technique.

Next, as shown in FIG. 3B, a dielectric layer 172 is formed on the dielectric layer 132, and a plurality of conductive layers 174 are formed in the dielectric layer 172, in accordance with some embodiments. The under bump metallization layers 176 are formed on the conductive layers 174, and the conductive connectors 178 are formed on the under bump metallization layers 176.

The dielectric layer 172 include silicon oxide (SiO₂), silicon nitride (SiN), silicon carbide (SiC), silicon oxynitride (SiON), silicon carbon nitride (SiCN), silicon oxide carbonitride (SiOCN), and a combination thereof. In some embodiments, the dielectric layer 172 may be formed by chemical vapor deposition (CVD), physical vapor deposition (PVD), plasma enhanced chemical vapor deposition (PECVD), spin coating, lamination or another suitable deposition technique.

In some embodiments, the conductive layers 174 are made of conductive materials, such as copper (Cu), copper alloy, aluminum (Al), aluminum alloys, combinations thereof or another applicable material. In some embodiments, the conductive layers 174 may be formed by chemical vapor deposition (CVD), physical vapor deposition (PVD), plasma enhanced chemical vapor deposition (PECVD), spin coating, lamination or another suitable deposition technique.

The under bump metallization layers 176 may contain an adhesion layer and/or a wetting layer. In some embodiments, the under bump metallization layers 176 are made of titanium (Ti), titanium nitride (TiN), tantalum nitride (TaN), tantalum (Ta), or the like. In some embodiments, the under bump metallization layers 176 further includes a copper seed layer. In some embodiments, the under bump metallization layers 176 are formed by electroplating, electroless plating, printing, a chemical vapor deposition (CVD) process, a physical vapor process, or another applicable process.

The conductive connectors 178 are made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 178 are formed by electroplating, electroless plating, printing, a chemical vapor deposition (CVD) process, a physical vapor process, or another applicable process.

Afterwards, as shown in FIG. 3C, a planarization process is performed on a backside surface of the substrate 122 to expose the through vias 126, and then a plurality of conductive layers 184 and a plurality of under bump metallization layers 186 are formed in the dielectric layer 182, in accordance with some embodiments. Afterwards, a plurality of conductive connectors 188 are formed below the under bump metallization layers 186 to form the interposer 170. In some embodiments, a portion of the substrate 122 is removed by a chemical polishing mechanical polishing (CMP) process.

The under bump metallization layers 186 may contain an adhesion layer and/or a wetting layer. In some embodiments, the under bump metallization layers 186 are made of titanium (Ti), titanium nitride (TiN), tantalum nitride (TaN), tantalum (Ta), or the like. In some embodiments, the under bump metallization layers 186 further includes a copper seed layer. In some embodiments, the under bump metallization layers 186 are formed by electroplating, electroless plating, printing, a chemical vapor deposition (CVD) process, a physical vapor process, or another applicable process.

The conductive connectors 188 are made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 188 are formed by electroplating, electroless plating, printing, a chemical vapor deposition (CVD) process, a physical vapor process, or another applicable process.

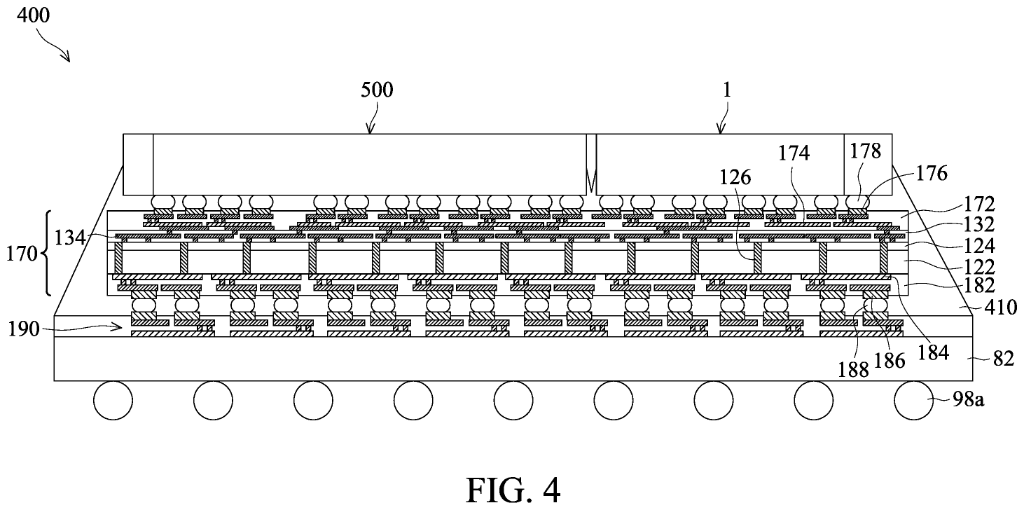

FIG. 4 illustrates a cross-sectional view of a package structure 400 including the interposer 170 illustrated in FIG. 3C, in accordance with some embodiments. As shown in FIG. 4, a semiconductor die 500 and the optical package structure 1 are bonded to the interposer 170, in accordance with some embodiments. In some embodiments, the semiconductor die 500 may be a memory die, a passive device die, an analog die, a microelectromechanical system (MEMS) die, or a radio frequency (RF) die.

The interposer 170 may be further bonded to a package substrate 82. A redistribution structure 190 may be formed between the interposer 170 and the package substrate 82. A plurality of conductive connectors 98a may be formed under the package substrate 82. In some embodiments, an underfill layer 410 is dispensed into the gap between the interposer 170 and the package substrate 82. In some embodiments, the underfill layer 410 includes a polymer, epoxy, molding underfill, or the like. In some embodiments, the underfill layer 410 is formed by a capillary flow process.

In short, a package structure 400 is provided. The package structure 400 includes the optical package structure 1. The optical package structure 1 includes the photonic integrated circuit die 10 including the coupler 24 and the electronic integrated circuit die 200 bonded to a first region of the photonic integrated circuit die 10. The optical package structure 1 also includes the oxide layer 260 formed over a second region of the photonic integrated circuit die 10 and adjacent to the electronic integrated circuit die 200. The optical package structure 1 further includes the silicon carrier 280 including the trench 282 exposing the top surface 260T of the oxide layer 260 and formed directly over the coupler 24.

In some embodiments, the package structure 400 further includes the semiconductor die 500 adjacent to the optical package structure 1. In some embodiments, the package structure 400 further includes the interposer 170, and the semiconductor die 500 and the optical package structure 1 are bonded to the interposer 170.

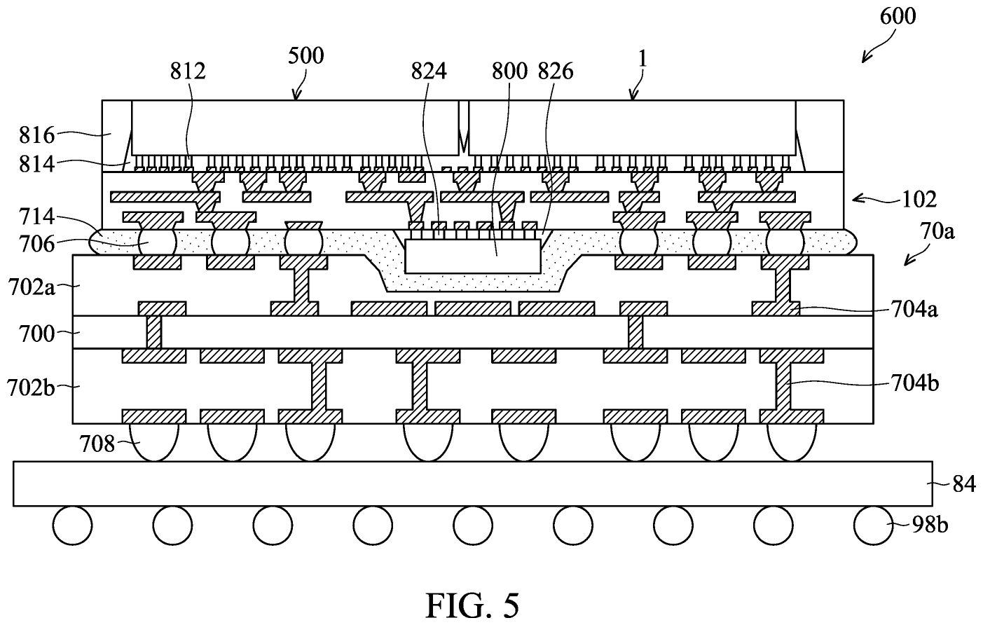

FIG. 5 illustrates a cross-sectional view of a package structure 600, in accordance with some embodiments. The package structure 600 includes the semiconductor die 500 and the optical package structure 1. The semiconductor die 500 and the optical package structure 1 are disposed on a redistribution structure 102 and bonded to a circuit substrate 70a.

In some embodiments, the semiconductor die 500 and the optical package structure 1 are bonded onto the conductive pads of the redistribution structure 102 through a plurality of conductive connectors 812. In some embodiments, the semiconductor die 500 and the optical package structure 1 both include a plurality of conductive pillars (or conductive pads) with solder elements formed thereon. Solder elements may also be formed on the conductive pads of the redistribution structure 102. The semiconductor die 500 and the optical package structure 1 are picked and placed onto the redistribution structure 102. In some embodiments, the solder elements of the semiconductor die 500 and the optical package structure 1 and/or the solder elements on the conductive pads of the redistribution structure 102 are reflowed together. As a result, the reflowed solder elements form the conductive connectors 812.

In some embodiments, an underfill material 814 is formed to surround and protect the conductive connectors 812. The underfill material 814 may be made of or include a polymer material, such as an epoxy-based resin with fillers dispersed therein. The fillers may include fibers (such as silica fibers and/or carbon-containing fibers), particles (such as silica particles and/or carbon-containing particles), or a combination thereof. Afterwards, a protective layer 816 is formed over the redistribution structure 102 to surround and protect the semiconductor die 500 and the optical package structure 1. In some embodiments, the protective layer 816 is in physical contact with the redistribution structure 102. In some embodiments, the protective layer 816 is separated from the conductive connectors 812 below the semiconductor die 500 and the optical package structure 1 by the underfill material 814.

The circuit substrate 70a may include a core portion 700, an insulating layer 702a, an insulating layer 702b, a plurality of conductive features 704a embedded in the insulating layer 702a, and a plurality of conductive features 704b embedded in the insulating layers 702b. The insulating layer 702a and the insulating layer 702b may be made of or include one or more polymer materials. The conductive features 704a and the conductive features 704b may be used to route electrical signals between opposite sides of the circuit substrate 70a. The conductive features 704a and the conductive features 704b may be made of conductive materials, such as copper (Cu), copper alloy, aluminum (Al), aluminum alloys, combinations thereof or another applicable material.

The core portion 700 may include organic materials such as materials that can be easily laminated. In some embodiments, the core portion 700 may include a single-sided or double-sided copper clad laminate, epoxy, resin, glass fiber, molding compound, plastic (such as polyvinylchloride (PVC), acrylonitrile, butadiene and styrene (ABS), polypropylene (PP), polyethylene (PE), polystyrene (PS), polymethyl methacrylate (PMMA), polyethylene terephthalate (PET), polycarbonates (PC), polyphenylene sulfide (PPS)), one or more other suitable elements, or a combination thereof. Conductive vias may extend through the core portion 700 to provide electrical connections between elements disposed on either side of the core portion 700. In some embodiments, the circuit substrate 70a further includes a plurality of conductive connectors 706 and a plurality of conductive connectors 708. In some embodiments, the conductive connectors 706 and the conductive connectors 708 are solder bumps. In some embodiments, an underfill material 714 that surrounds the conductive connectors 706 may be formed. In some embodiments, the conductive connectors 708 are used to bond with a package substrate 84. A plurality of conductive connectors 98b may be formed under the package substrate 84.

An underfill liquid 712 is dispensed onto the circuit substrate 70a along a side of the semiconductor die 500, in accordance with some embodiments. The underfill liquid 712 may be made of or include a polymer material, such as an epoxy-based resin with fillers dispersed therein. The fillers may include fibers (such as silica fibers and/or carbon-containing fibers), particles (such as silica particles and/or carbon-containing particles), or a combination thereof. The underfill liquid 712 may be drawn into the space between the semiconductor die 500 and the circuit substrate 70a to surround some of the conductive connectors 706 by the capillary force.

In some embodiments, one or more chip structures (or may be referred to as chip-containing structures) 800 may be bonded to the redistribution structure 102 through a plurality of conductive connectors 824, in accordance with some embodiments. In some embodiments, an underfill material 826 may be formed to surround the conductive connectors 824. In some embodiments, the chip structure 800 forms electrical connections between the semiconductor die 500 and the optical package structure 1.

As described above, an optical package structure, a package structure including the optical package structure, and a method for forming the optical package structure are provided. A silicon carrier included in the optical package structure has a trench for placing a fiber array unit, and thus optical signals leaving the fiber array do not have to pass through the silicon carrier before entering a coupler, thereby effectively shorten the optical path. The optical coupling on the coupler is further improved. In addition, the trench may be formed directly over the coupler, so the alignment accuracy between the fiber array unit and the coupler is improved. Furthermore, transmission speed of optical signals may become faster, and power consumption can be reduced.

Some embodiments of the present disclosure provide an optical package structure. The optical package structure includes a photonic integrated circuit die, an electronic integrated circuit die, an oxide layer, and a silicon carrier. The photonic integrated circuit die includes a coupler. The electronic integrated circuit die is bonded to the photonic integrated circuit die. The oxide layer is adjacent to the electronic integrated circuit die. The silicon carrier includes a first part over the electronic integrated circuit die and a second part over the oxide layer. A trench is formed in the second part of the silicon carrier.

In some embodiments, the trench at least partially overlaps the coupler vertically. In some embodiments, the width of the first part is greater than the width of the electronic integrated circuit die. In some embodiments, the width of the first part of the silicon carrier is greater than the width of the second part of the silicon carrier. In some embodiments, the thickness of the first part of the silicon carrier is greater than the thickness of the oxide layer. In some embodiments, the optical package structure further includes a dielectric layer and a metal reflector formed in the dielectric layer, and the metal reflector is formed under the oxide layer. In some embodiments, the metal reflector at least partially overlaps the coupler and the trench vertically. In some embodiments, the width of the metal reflector is greater than the width of the coupler.

In some embodiments, the optical package structure further includes a plurality of conductive connectors and a plurality of dummy conductive connectors formed under the dielectric layer. In some embodiments, the conductive connectors are electrically connected to the electronic integrated circuit die, and the dummy conductive connectors are not electrically connected to the electronic integrated circuit die. In some embodiments, each dummy conductive connector at least partially overlaps the metal reflector vertically. In some embodiments, the photonic integrated circuit die further includes a waveguide adjacent to the coupler.

Some embodiments of the present disclosure provide a package structure including an optical package structure. The optical package structure includes a photonic integrated circuit die, an electronic integrated circuit die, an oxide layer, and a silicon carrier. The photonic integrated circuit die includes a coupler. The electronic integrated circuit die is bonded to a first region of the photonic integrated circuit die. The oxide layer is formed over a second region of the photonic integrated circuit die and adjacent to the electronic integrated circuit die. The silicon carrier includes a trench exposing a top surface of the oxide layer and formed directly over the coupler.

In some embodiments, the package structure further includes a semiconductor die adjacent to the optical package structure. In some embodiments, the package structure further includes an interposer, and the semiconductor die and the optical package structure are bonded to the interposer.

Some embodiments of the present disclosure provide a method for forming an optical package structure. The method includes forming a photonic integrated circuit die and forming an electronic integrated circuit die over the photonic integrated circuit die The method also includes forming an oxide layer adjacent to the electronic integrated circuit die. The method further includes attaching a silicon carrier to the electronic integrated circuit die and the oxide layer and forming a trench in the silicon carrier, so that part of the top surface of the oxide layer is exposed. In some embodiments, the top surface of the oxide layer is substantially level with the top surface of the electronic integrated circuit die.

In some embodiments, the photonic integrated circuit die includes a substrate and a coupler over the substrate. In some embodiments, the trench is formed directly over the coupler. In some embodiments, the method further includes removing the substrate of the photonic integrated circuit die after the trench is formed. In some embodiments, the method further includes placing a fiber array unit in the trench, and an optical signal leaving the fiber array unit enters the coupler without passing through the silicon carrier.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical package structure, comprising:
a photonic integrated circuit die comprising a coupler;
an electronic integrated circuit die bonded to the photonic integrated circuit die;
an oxide layer adjacent to the electronic integrated circuit die; and
a silicon carrier comprising a first part over the electronic integrated circuit die and a second part over the oxide layer,
wherein a trench is formed in the second part of the silicon carrier.

2. The optical package structure as claimed in claim 1, wherein the trench at least partially overlaps the coupler vertically.

3. The optical package structure as claimed in claim 1, wherein a width of the first part is greater than a width of the electronic integrated circuit die.

4. The optical package structure as claimed in claim 1, wherein a width of the first part of the silicon carrier is greater than a width of the second part of the silicon carrier.

5. The optical package structure as claimed in claim 1, wherein a thickness of the first part of the silicon carrier is greater than a thickness of the oxide layer.

6. The optical package structure as claimed in claim 1, further comprising a dielectric layer and a metal reflector formed in the dielectric layer, wherein the metal reflector is formed under the oxide layer.

7. The optical package structure as claimed in claim 6, wherein the metal reflector at least partially overlaps the coupler and the trench vertically.

8. The optical package structure as claimed in claim 7, wherein a width of the metal reflector is greater than a width of the coupler.

9. The optical package structure as claimed in claim 6, further comprising a plurality of conductive connectors and a plurality of dummy conductive connectors formed under the dielectric layer.

10. The optical package structure as claimed in claim 9, wherein the plurality of conductive connectors are electrically connected to the electronic integrated circuit die, and the plurality of dummy conductive connectors are not electrically connected to the electronic integrated circuit die.

11. The optical package structure as claimed in claim 10, wherein each of the plurality of dummy conductive connectors at least partially overlaps the metal reflector vertically.

12. The optical package structure as claimed in claim 1, wherein the photonic integrated circuit die further comprises a waveguide adjacent to the coupler.

13. A package structure, comprising:
an optical package structure comprising:
a photonic integrated circuit die comprising a coupler;
an electronic integrated circuit die bonded to a first region of the photonic integrated circuit die;
an oxide layer formed over a second region of the photonic integrated circuit die and adjacent to the electronic integrated circuit die; and
a silicon carrier comprising a trench exposing a top surface of the oxide layer and formed directly over the coupler.

14. The package structure as claimed in claim 13, further comprising a semiconductor die adjacent to the optical package structure.

15. The package structure as claimed in claim 14, further comprising an interposer, wherein the semiconductor die and the optical package structure are bonded to the interposer.

16. A method for forming an optical package structure, comprising:
forming a photonic integrated circuit die;
forming an electronic integrated circuit die over the photonic integrated circuit die;
forming an oxide layer adjacent to the electronic integrated circuit die, wherein a top surface of the oxide layer is substantially level with a top surface of the electronic integrated circuit die;
attaching a silicon carrier to the electronic integrated circuit die and the oxide layer; and
forming a trench in the silicon carrier, so that part of the top surface of the oxide layer is exposed.

17. The method as claimed in claim 16, wherein the photonic integrated circuit die comprises a substrate and a coupler over the substrate.

18. The method as claimed in claim 17, wherein the trench is formed directly over the coupler.

19. The method as claimed in claim 17, further comprising removing the substrate of the photonic integrated circuit die after the trench is formed.

20. The method as claimed in claim 17, further comprising placing a fiber array unit in the trench, wherein an optical signal leaving the fiber array unit enters the coupler without passing through the silicon carrier.
